(19) United States
(12) Patent Application Publication
(10) Pub. No.: US 2026/0173721 A1
(43) Pub. Date: Jun. 18, 2026

(54) DISPLAY PANEL AND METHOD FOR MANUFACTURING SAME, AND DISPLAY DEVICE

(71) Applicant: BOE Technology Group Co., Ltd., Beijing (CN)

(72) Inventors: Qing DAI, Beijing (CN); Zhuo CHEN, Beijing (CN)

(21) Appl. No.: 18/846,227

(22) PCT Filed: Oct. 30, 2023
(86) PCT No.: PCT/CN2023/127915

§ 371 Date: Sep. 11, 2024

(51) Int. Cl. H10K 59/80; H10K 59/12

(52) U.S. Cl. CPC H10K 59/873; H10K 59/1201

(57) ABSTRACT

A display panel and a method for manufacturing the same, and a display device are provided. The display panel includes a display substrate and a draining structure, wherein the display substrate includes a display region and a first peripheral region, and the draining structure is disposed on a first surface of the display substrate. The draining structure includes a plurality of first bunch structures, the plurality of first bunch structures is disposed in the first peripheral region. The plurality of first bunch structures is arranged around the display region, each of the first bunch structure has a first collection groove, each of the first bunch structure includes a plurality of first rib structures arranged in a circumferential row around the first collection groove, and the plurality of first rib structures is configured to direct droplets into the first collection groove surrounded by the plurality of first rib structures.

The present application is a national stage of PCT application No. PCT/CN2023/127915, filed on Oct. 30, 2023, the entire contents of which are incorporated herein by reference.

### TECHNICAL FIELD

The present disclosure related the field of display technology, and in particular, relates to a display panel and a method for manufacturing the same, and a display device.

### BACKGROUND

Display devices have wide application scenarios in life, such as mobile phones, tablet computers and other electronic devices. The display panel is an important component of the display device.

In the related technology, the display panel includes a display substrate and a draining structure, the display substrate includes a display region and a peripheral region, the peripheral region surrounds the display region, and the draining structure is disposed in the peripheral region. The draining structure includes a plurality of blocking structures disposed in parallel and a collection groove disposed between the plurality of blocking structures. The blocking structures extend in a direction parallel to an extending direction of an edge of the display region.

However, droplets (e.g., ink of the light-emitting material) falling on the plurality of blocking walls disposed in parallel may randomly move and gather to form larger droplets, which may form a connection path upon drying, and outside water and oxygen may enter the interior of the display panel through the connection path and affect the encapsulation effect of the display panel.

### SUMMARY

Embodiments of the present disclosure provide a display panel and a method for manufacturing the same, and a display device. The technical solutions are as follows.

In one aspect, a display panel is provided. The display panel includes a display substrate and a draining structure, wherein the display substrate includes a display region and a first peripheral region disposed at an edge of the display region, and the draining structure is disposed on a first surface of the display substrate; wherein the draining structure includes a plurality of first bunch structures, the plurality of first bunch structures is disposed in the first peripheral region, the plurality of first bunch structures is arranged around the display region, each of the first bunch structure has a first collection groove, each of the first bunch structure includes a plurality of first rib structures arranged in a circumferential row around the first collection groove, and the plurality of first rib structures is configured to direct droplets into the first collection groove surrounded by the plurality of first rib structures.

Optionally, each of the first rib structures has a first end close to the first collection groove and a second end away from the first collection groove, and a distance between two of the first rib structures adjacent in the circumferential row is gradually increasing in a direction from the first end to the second end.

Optionally, in at least one of the first bunch structures, the first ends of the plurality of first rib structures are connected.

Optionally, the plurality of first bunch structures is divided into at least two first bunch structure groups, the at least two first bunch structure groups are arranged in a direction away from the display region, and first bunch structures in each of the first bunch structure groups are arranged sequentially in a circumferential row around the display region.

Optionally, the plurality of first bunch structures is sequentially arranged in a circumferential row around the display region.

Optionally, a shape formed by sequentially connecting second ends of each of the first bunch structures is identical; or a shape formed by sequentially connecting second ends of at least two of the first bunch structures are different.

Optionally, the plurality of first bunch structures includes a first target rib structure and a second target rib structure, and a distance between the first bunch structure group to which the first target rib structure belongs and the display region is shorter than a distance between the first bunch structure group to which the second target rib structure belongs and the display region; and a length of the first target rib structure is different from a length of the second target rib structure.

Optionally, a distance between two adjacent first bunch structures ranges from 2 μm to 8 μm.

Optionally, a diameter of the first collection groove ranges from 1 mm to 10 mm, and a depth of the first collection groove ranges from 0.5 μm to 5 μm.

Optionally, the first rib structure has a top surface which is away from the first surface, at least one first cross-section of the first rib structure is parallel to the first surface, and a width of the top surface is greater than a width of the first cross-section.

Optionally, a length of the first rib structure ranges from 10 μm to 500 μm.

Optionally, the display substrate includes a substrate, a driving circuit layer and a light-emitting functional layer which are stacked sequentially, and the driving circuit layer and the light-emitting functional layer are disposed in the display region, wherein the driving circuit layer includes a source-drain layer, and the first rib structures are in the same layer as the source-drain layer.

Optionally, the light-emitting functional layer includes a first electrode layer, a light-emitting layer and a second electrode layer which are stacked sequentially on the first surface; wherein the light-emitting layer is an organic light-emitting layer, or the light-emitting layer is a quantum dot light-emitting layer.

Optionally, the draining structure further includes a lyophobic film, and the lyophobic film is disposed on a side, away from the first surface, of the plurality of first bunch structures.

Optionally, the display substrate further includes at least one opening region and at least one second peripheral region, the display region surrounds the at least one opening region, the at least one second peripheral region is in one-to-one correspondence with the at least one opening region, and the at least one second peripheral region is disposed between the at least one opening region and the display region; and the draining structure further includes a plurality of second bunch structures, the plurality of second bunch structures are disposed in the at least one second peripheral region, the plurality of second bunch structures is arranged around the at least one opening region, each of the second bunch structures has a second collection groove, and each of the second bunch structures includes a plurality of second rib structures arranged in a circumferential row around the second collection groove, and the plurality of second rib structures is configured to direct droplets into the second collection groove surrounded by the plurality of second rib structures

In another aspect, a method for manufacturing a display panel is provided. The method includes: providing a display substrate, wherein the display substrate includes a display region and a first peripheral region disposed at an edge of the display region; and forming a draining structure on a first surface of the display substrate; wherein the draining structure includes a plurality of first bunch structures, the plurality of first bunch structures is disposed in the first peripheral region, the plurality of first bunch structures is arranged around the display region, each of the first bunch structure has a first collection grooves, each of the first bunch structures includes a plurality of first rib structures arranged in a circumferential row around the first collection groove, and the plurality of first rib structures is configured to direct droplets into the first collection groove surrounded by the plurality of first rib structures.

In still another aspect, a display device is provided. The display device includes a power supply circuit and the display panel described in any of the above embodiments, wherein the power supply circuit is configured to supply power to the display panel.

### BRIEF DESCRIPTION OF DRAWINGS

In order to more clearly illustrate the technical solutions in the embodiments of the present disclosure, the accompanying drawings that need to be used in the description of the embodiments are briefly introduced below. It is obvious that the accompanying drawings in the following description are only some of the embodiments of the present disclosure, and a person of ordinary skill in the art can acquire other accompanying drawings based on these drawings without creative labor.

FIG. 1 is a schematic diagram of a planar structure of a display panel according to some embodiments of the present disclosure;

FIG. 2 is a schematic diagram of a cross-sectional structure of a display panel according to some embodiments of the present disclosure;

FIG. 3 is a schematic diagram of a planar structure of a first bunch structure according to some embodiments of the present disclosure;

FIG. 4 is a schematic diagram of a planar structure of another first bunch structure according to some embodiments of the present disclosure;

FIG. 5 is a partially enlarged schematic diagram of a first bunch structure according to some embodiments of the present disclosure;

FIG. 6 is a schematic diagram of droplets falling on a first rib structure according to some embodiments of the present disclosure;

FIG. 7 is a schematic diagram of a cross-sectional structure of a first rib structure according to some embodiments of the present disclosure;

FIG. 8 is a schematic diagram of an arrangement of first bunch structures according to some embodiments of the present disclosure;

FIG. 9 is a schematic diagram of a planar structure of another display panel and a schematic diagram of the arrangement of the corresponding first bunch structures according to some embodiments of the present disclosure;

FIG. 10 is a schematic diagram of a planar structure of another display panel and a schematic diagram of the arrangement of the corresponding first bunch structures according to some embodiments of the present disclosure;

FIG. 11 is a schematic diagram of a planar structure of two adjacent first bunch structures according to some embodiments of the present disclosure;

FIG. 12 is a schematic diagram of a cross-sectional structure of another display panel according to some embodiments of the present disclosure;

FIG. 13 is a schematic diagram of a cross-sectional structure of a display region of another display panel according to some embodiments of the present disclosure;

FIG. 14 is a schematic diagram of a planar structure of another display panel according to some embodiments of the present disclosure;

FIG. 15 is a schematic flow diagram of a method for manufacturing a display panel according to some embodiments of the present disclosure; and

FIG. 16 is a schematic diagram of a light-emitting layer formed by an all-round coating manner according to some embodiments of the present disclosure.

### FIGURE MARK ILLUSTRATION

1—display substrate; 11—display region; 12—first peripheral region; 13—opening region; 14—second peripheral region; A—first surface;

2—draining structure; 20a—first bunch structure group; 20—first bunch structure; 201—first rib structure; 202—first collection groove; 201a—first end; 201b—second end; 201c—top surface; 201d—first cross section; 21—second bunch structure; 2011—first target rib structure; 2012—second target rib structure;

3—driving circuit layer; 301—light shielding layer; 302—first gate layer; 303—second gate layer; 304—third gate layer; 305—first source-drain layer; 306—second source-drain layer; 307—first semiconductor layer; 308—second semiconductor layer; 309—buffer layer; 310—first gate insulating layer; 311—first insulating layer; 312—second gate insulating layer; 313—third gate insulating layer; 314—interlayer dielectric layer; 315—passivation layer; 316—first planarization layer; 317—second planarization layer; and

4—light-emitting functional layer; 41—first electrode layer; 42—light-emitting layer; 43—second electrode layer; 44—pixel definition layer; 5—encapsulation layer; 6—color transfer layer; 7—color film layer; 8—substrate.

### DETAILED DESCRIPTION

In order to make the objects, technical solutions and advantages of the present disclosure clearer, the embodiments of the present application are described in further detail below in conjunction with the accompanying drawings.

The terms used in the embodiments portion of the present disclosure are used only for the purpose of explaining the embodiments of the present disclosure and are not intended to limit the present disclosure. Unless otherwise defined, technical terms or scientific terms used in the embodiments of the present disclosure shall have the ordinary meaning understood by a person of ordinary skill in the art to which the present disclosure belongs. The terms “first,” “second,” “third,” and the like used in the description of the patent application and the claims of the present disclosure do not indicate any order, number, or importance, but are merely used to distinguish different components. Similarly, the words “a” or “one” and similar terms do not indicate a limitation of quantity, but rather the existence of at least one. Similar terms such as “includes” or “contains” mean that the components or objects appearing prior to “includes” or “contains” encompasses the components or objects that appearing upon “includes” or “contains”, and do not exclude other components or objects. Orientation terms mentioned in the present disclosure, such as “top”, “bottom”, “up”, “down”, “left”, “right”, or the like, are only references to the orientation of the accompanying drawings. Therefore, the orientation terms used are intended to better and more clearly illustrate and understand the present disclosure embodiments, and do not indicate or imply that the device or component referred to must have a particular orientation, or be constructed and operated in a particular orientation, which are not to be construed as a limitation of the embodiments of the present disclosure.

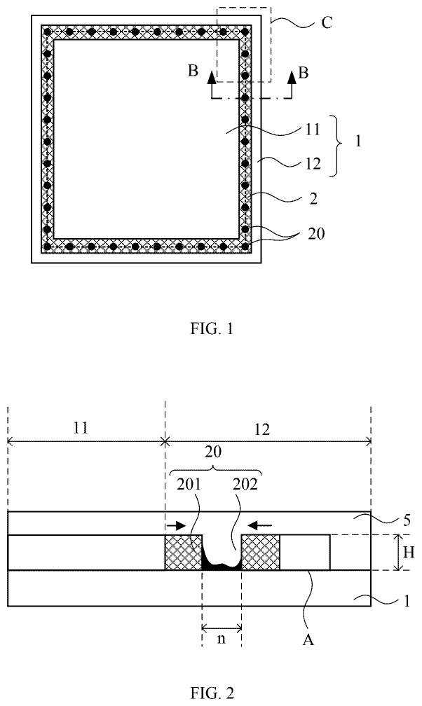

FIG. 1 is a schematic diagram of a planar structure of a display panel according to some embodiments of the present disclosure. As shown in FIG. 1, the display panel includes a display substrate 1 and a draining structure 2. The display substrate 1 includes a display region 11 and a first peripheral region 12 disposed at the edge of the display region 11. The draining structure 2 is disposed in the first peripheral region 12. The draining structure 2 includes a plurality of first bunch structures 20, and the plurality of first bunch structures 20 is arranged around the display region 11.

FIG. 2 is a schematic diagram of a cross-sectional structure of a display panel according to some embodiments of the present disclosure. FIG. 2 is a schematic diagram of the cross-sectional structure at a BB cross-sectional line of FIG. 1. As shown in FIG. 2, the draining structure 2 is disposed on a first surface A of the display substrate.

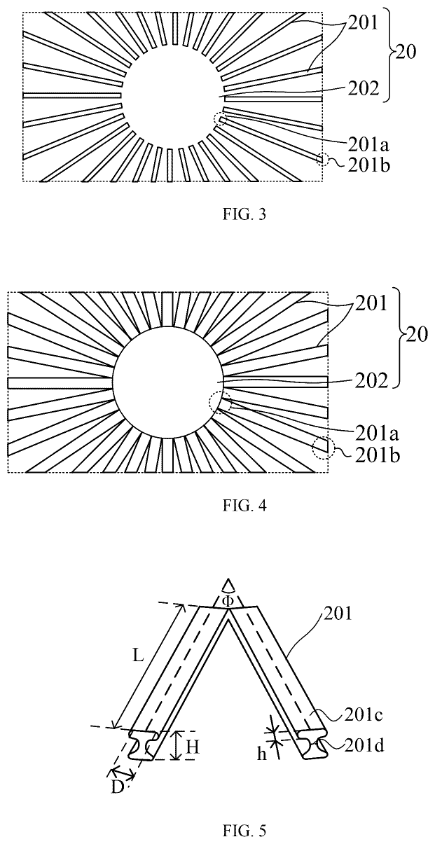

FIG. 3 is a schematic diagram of a planar structure of a first bunch structure according to some embodiments of the present disclosure, and FIG. 3 is a partially enlarged view of one of the first bunch structures in FIG. 1. In conjunction with FIGS. 1 to 3, each of the first bunch structure 20 has a first collection groove 202, the first bunch structure 20 includes a plurality of first rib structures 201 arranged in a circumferential row around the first collection groove 202, and the plurality of first rib structures 201 are configured to direct droplets into the first collection groove 202 surrounded by the plurality of first rib structures 201.

The droplets herein are inks of the light-emitting layer material. The display region 11 includes sub-pixel regions arranged in an array. Since at least a portion of the film layer structures in the light-emitting layer are shared by a plurality of sub-pixels, it is common to form these film layers by an all-round coating. For example, the ink is coated all over the first surface, and thus a situation that the droplets fall onto the first peripheral region 12 occurs.

Because the first rib structure 201 can direct the droplets to the first collection groove 202 surrounded by the plurality of first rib structures 201, the droplets disposed in the first collection groove 202 are disconnected from the droplets disposed in the display region 11. There is no connecting path between the dried droplets disposed in the first collection groove 202 and the dried droplets disposed in the display region 11, such that the encapsulation effect is better.

In order to clearly demonstrate more structure in FIG. 3, it should be noted that the first collection groove 202 in FIG. 3 does not correspond to the feature using a black fill to illustrate the dried droplets gathering in the first collection groove 202 in FIG. 1 or FIG. 2.

The structure in a first bunch structure 20 is described below.

In the embodiments of the present disclosure, as shown in FIG. 3, a first end 201a of each of the first rib structures 201 is close to the first collection groove 202, and a second end 201b of each of the first rib structures 201 is away from the first collection groove. The distance between two of the first rib structures adjacent in the circumferential row is gradually increasing in a direction from the first end 201a to the second end 201b. Therefore, the droplets on the first rib structure 201 are subjected to an unbalanced force, and the droplets are dynamically moved. The droplets falling into the first peripheral region 12 move along the circumferentially arranged first rib structures 201 in the direction of the gathered first rib structures 201 (i.e., in the direction from the second end 201b to the first end 201a), and flow into the first collection groove 202, such that the droplets disposed in the display region 11 are separated from the droplets disposed in the first peripheral region 12.

In the first bunch structure 20 as shown in FIG. 3, the first ends 201a of the plurality of first rib structures 201 are not connected, such that gaps are formed on the sidewalls of the first collection groove 202. But due to the surface tension of the droplets, the droplets flowing into the first collection groove 202 do not flow out through these gaps.

In the actual manufacturing process, the first bunch structure 20 is usually manufactured by a series of processes such as deposition, photoresist coating, exposure, development, etching, stripping. Due to the process precision limitation, when manufacturing the first bunch structure as shown in FIG. 3, the first ends 201a of the plurality of first rib structures 201 are actually mostly connected, that is, the sidewalls of the first collection groove 202 almost do not have any gaps, and the droplets flowing into the first collection groove 202 are less likely to flow out through the sidewalls of the first collection groove 202.

FIG. 4 is a schematic diagram of a planar structure of another first bunch structure according to some embodiments of the present disclosure. As shown in FIG. 4, in the first bunch structure 20, the plurality of first rib structures 201 is connected at the first end 201a. That is, the sidewalls of the formed first collection groove 202 do not have gaps, which further ensures that droplets flowing into the first collection groove 202 do not leak out of the sidewalls of the first collection groove 202.

Therefore, in the case that the first bunch structure is the embodiment shown in FIG. 3 or FIG. 4, the droplets between the first collection grooves 202 prior to drying are not connected, and the solute of the dried droplet in the first collection grooves 202 are also isolated from each other, which can realize the function of blocking water and oxygen. In the case that the above adsorption treatment is performed to the droplets prior to drying or the above step of wiping treatment is performed to the droplets upon drying, the residual amount of solute of the droplet can be further reduced, such that blocking effect to the water and oxygen is enhanced.

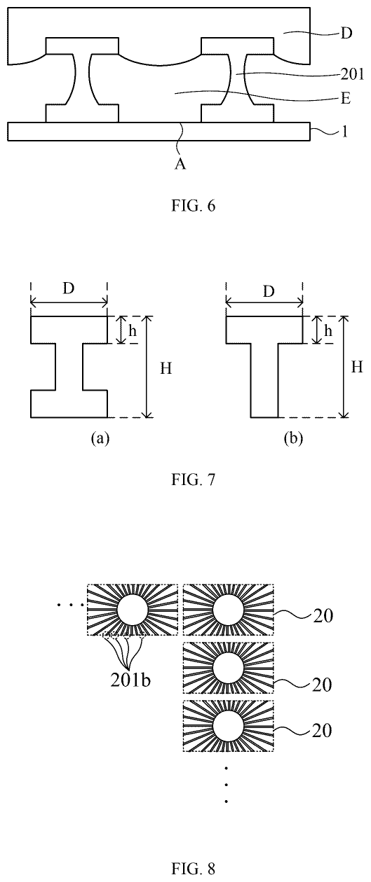

FIG. 5 is a partially enlarged schematic diagram of the first bunch structure according to some embodiments of the present disclosure. FIG. 6 is a schematic diagram of a droplet falling on the first rib structure according to some embodiments of the present disclosure. As shown in FIGS. 5 and 6, the first rib structure 201 has a top surface 201c which is away from the first surface A. The first rib structure 201 has at least one first cross-section 201d, and the first cross-section 201d is parallel to the first surface A. A width D of the top surface 201 c is greater than a width of the first cross-section. This design that the top surface 201c has a larger width and the first cross-section 201d has a smaller width forms a larger gap at the portion below the top surface 201c. In the case that a droplet D falls on the first rib structure 201, the inner sealing air E in the gap can support the droplet on the first rib structure 201, such that the droplet D does not fall to the bottom of the gap between two adjacent first rib structures 201, and is not directed into the first collection groove 202. The inner sealing air E id also referred to as an air column.

Exemplarily, as shown in FIG. 5, in a first bunch structure, the angle Φ formed by two adjacent first rib structures 201, and the width D of the top surface numerically satisfy the following relationship: Φ<0.12D+0.3, wherein the unit of the angle Φ is degree and the unit of the width D is μm. The inventor concludes based on the test results that when Φ and D satisfy this relationship equation, the droplets falling on the first rib structure 201 can be directed into the corresponding first collection groove 202. When Φ>0.12D+0.3, the second ends 201b of two adjacent first rib structures 201 are too far apart, and the droplets fall directly to the bottom of the first bunch structure 20.

Exemplarily, the width D of the top surface 201c ranges from 2 μm to 20 μm. A top surface 201c that is too narrow results in droplets falling directly to the bottom of the first bunch structure 20, and a top surface 201c that is too wide is not beneficial to forming an air column at the bottom between the two circumferentially adjacent first rib structures 201 and thus is hard to carry the droplets. Optionally, the width D may be 2 μm, 4 μm, 6 μm, 8 μm, 10 μm, 12 μm, 14 μm, 16 μm, 18 μm or 20 μm.

Exemplarily, the angle Φ ranges from 0.1° to 2°. An angle that is too large causes the droplets to directly fall to the bottom of the first bunch structure 20, and an angle that is too small is not beneficial to forming an air column between two circumferentially adjacent first rib structures 201 and thus is hard to carry the droplets. Optionally, the angle Φ may be 0.1°, 0.2°, 0.3°, 0.5°, 0.8°, 1°, 1.2°, 1.3°, 1.5°, 1.8°or 2°.

Exemplarily, as shown in FIG. 5, the length L of the first rib structure 201 ranges from 10 μm to 500 μm. In the case that the first rib structure 201 is too short, the droplets are easily adhered and hard to be separated, which is difficult to realize the function of directing the droplets into the first collection groove 202. In the case that the first rib structure 201 is too long, the distance between the second ends 201b of the two circumferentially adjacent first rib structures 201 is too long, and the liquid surface tension is insufficient to support the droplets at the second end 201b, which causes the droplets to directly fall to the bottom of the first bunch structure.

FIG. 7 is a schematic diagram of a cross-sectional structure of the first rib structure according to some embodiments of the present disclosure, and the cross-sectional section is perpendicular to the first surface. The cross-section of the first rib structure 201 is I-shaped as shown in part (a) of FIG. 7, or T-shaped as shown in part (b) of FIG. 7, or other shapes.

Exemplarily, referring again to FIG. 2, the diameter n of the first collection groove 202 ranges from 1 mm to 10 mm. In conjunction with FIGS. 2 and 5, the depth H of the first collection groove 202 ranges from 0.5 μm to 5 μm, i.e., the height H of the first rib structure 201 ranges from 0.5 μm to 5 μm. The diameter of the first collection groove 202 that is too large is not beneficial to a narrow bezel, while the diameter that is too small cannot provide sufficient space for collecting droplets. The height of the first collection groove 202 that is too small causes collection space to be insufficient, or the air column below the first rib structure to be not sufficient to support the droplets on the first rib structure, such that the droplets are contacted with the bottom of the first bunch structure 20 and flow into the bottom, which increases the difficulty of manufacturing the I-shape or T-shape first rib structure. The height of the first collection groove 202 that is too large, i.e., the height of the first rib structure 201 that is too large, leads to a higher difficulty of manufacturing the first rib structure 201.

In some embodiments of the present disclosure, the micro-nanostructure that a plurality of first rib structures 201 of the first bunch structure 20 is arranged circumferentially around the first collection groove 202 has a lyophobic property. The draining structure 2 further includes a lyophobic film, and the lyophobic film is disposed on a side, away from the first surface A, of the plurality of first bunch structures 20. In the case that the droplets are on the first bunch structures 20, an external stimulus, such as light or temperature, is applied to the first rib structure 201 to enhance the lyophobic property of the surface of the first rib structure 201, which facilitates the first rib structure 201 to direct the droplets on the first bunch structures 20 into the first collection groove 202. Optionally, the material of the lyophobic film is a light-sensitive or temperature-sensitive material, such as poly N-isopropylacrylamide (PNIPAM).

In some embodiments of the present disclosure, the first peripheral region 12 includes an encapsulation region and a binding region. For the first bunch 20 in the encapsulation region, referring again to FIG. 2, solute of the droplets upon drying is left in the first collection groove 202. The display panel further includes an encapsulation layer 5, and the material of the encapsulation layer is also filled in the first collection groove 202.

Optionally, an adsorption treatment can be performed on the droplets in the first collection groove 202 in the case that the droplets are not dry, or a wiping treatment can be performed on the solute of the droplets upon drying left in the first collection groove 202, such that the first collection groove 202 does not accommodate the organic material formed by the dried droplets, or accommodates a very small amount of organic material formed by the dried droplets, in addition to the encapsulation layer material. In the case that the wiping treatment is performed, because the first rib structure 201 is between the first collection groove 202 and the display region 11, and the first collection groove 202 is not directly contacted with the display region 11, the organic film layer formed in the display region such as the light-emitting layer is not affected.

Optionally, the encapsulation layer includes an organic encapsulation layer and an inorganic encapsulation layer which are sequentially stacked in the direction of first bunch structure away from the first surface. The organic encapsulation layer is sufficiently filled in the gaps between the plurality of first rib structures 201 and the first collection groove 202. The inorganic encapsulation layer prevents outside water and oxygen from entering the interior of the display panel.

Optionally, the organic encapsulation layer is made of a material such as polyimide, polyamide, acrylic resin, or phenolic resin.

Optionally, the inorganic encapsulation layer is made of a material such as silicon nitride, silicon oxide or silicon nitride.

In other possible embodiments, the first bunch structure 20 is disposed in a binding region within the first peripheral region 12, and a conductive adhesive is disposed within the first collection groove 202. That is, the conductive adhesive and solute of the droplets upon drying are in the first collection groove 202, or only the conductive adhesive for binding is in the first collection groove 202. Since the droplets are mostly organic materials, in the case that the draining structure in the related technology is applied here, the larger droplets formed by randomly moving and gathering form a connection path with a higher resistance upon drying, which affects the other circuits in the binding region to conduct electricity well. Optionally, the droplets in the first collection groove 202 are also adsorbed prior to drying, such that the solute left in the first collection groove 202 within the binding region is reduced.

FIG. 8 is a schematic diagram of an arrangement of a first bunch structure according to some embodiments of the present disclosure, and FIG. 8 is also a partially enlarged schematic diagram of the region C in FIG. 1. As shown in FIG. 8, the plurality of first bunch structures 20 is arranged sequentially in a circumferential row around the display region 11. Because at most only one first bunch structure 20 is disposed in the direction from a side close to the display region 11 to a side away from the display region 11, the design facilitates a narrow frame of the product.

Exemplarily, as shown in FIG. 8, the plurality of second ends of each of the first bunch structures 20 are sequentially connected to form the same shapes. Such design of the shapes of the plurality of first bunch structures 20 enables the first bunch structures 20 to be adapted to some shapes of the display region 11, such as the rectangular display region 11 in the embodiments shown in FIGS. 1 and 5. Optionally, as shown in FIGS. 1 and 5, a shape formed by sequentially connecting the plurality of second ends 201b of each of the first bunch structures 20 are rectangular. This design allows the draining structure 2 to have a more uniform radial dimension at the straight edges and four right angles of the display region 11.

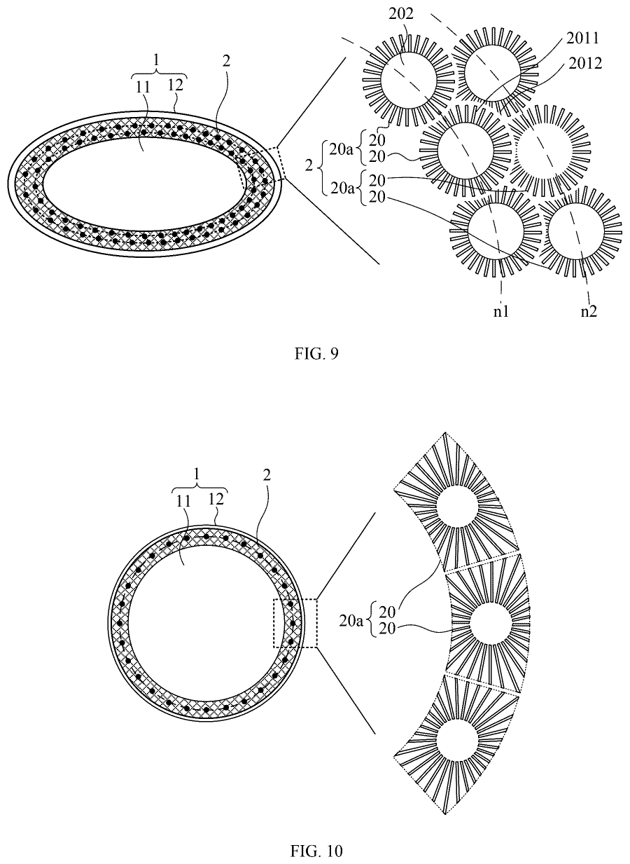

FIG. 9 is a schematic diagram of a planar structure of another display panel and a schematic diagram of the arrangement of the corresponding first bunch structure according to some embodiments of the present disclosure. Compared to the embodiments shown in FIGS. 1 and 8, in the embodiment shown in FIG. 9, the plurality of first bunch structures 20 is divided into two first bunch structure groups 20a, the two first bunch structure groups 20a are arranged in a direction away from the display region 11, and the plurality of first bunch structures 20 in each of the first bunch structure groups 20a is arranged sequentially in a circumferential row around the display region 11. The arrangement of a plurality of first bunch structure groups 20a increases the radial dimension of the draining structure 2, which allows for better directing the droplets in the first peripheral region into the first collection groove 202.

In other possible embodiments, three or more first bunch structure groups 20a are designed based on the design requirements, these first bunch structure groups 20a are arranged in a direction away from the display region 11, and each of the first bunch structure groups 20a includes a plurality of first bunch structures 20 around the display region 11.

Exemplarily, as shown in FIG. 9, the centers of the first collection grooves 202 of the plurality of first bunch structures 20 are arranged along a line n1 in the first bunch structure group 20a close to the display region 11. The centers of the first collection grooves 202 of the plurality of first bunch structures 20 are arranged along a line n2 in the first bunch structure group 20a away from the display region 11. The extending directions of the lines n1 and n2 are the same as the extending direction of the edges of the display region 11, such that within a first bunch structure group, the distances from the edges of the display region 11 to the first collection grooves 202 is identical, which results in more uniform width dimensions at various places of the frame of the display panel.

Exemplarily, as shown in FIG. 9, in the case that the draining structure 2 includes two first bunch structure groups 20a, in a direction pointing from the center of the display region 11 to the edge of the display region 11, the direction passes through at most a center of one first collection groove. This design allows the first collection grooves of the two first bunch structure groups to be interleaved as much as possible to more fully collect droplets from all parts of the first peripheral region 12.

In other possible embodiments, in the case that the draining structure 2 includes N first bunch structure groups 20, wherein N≥3 and N is an integer, a direction pointing from the center of the display region 11 to the edge of the display region 11, the direction passes through at most centers of N-1 first collection grooves in. This design allows the first collection grooves of the N first bunch structure groups to be interleaved as much as possible to more fully collect droplets from all parts of the first peripheral region 12.

Exemplarily, as shown in FIG. 9, shapes of the edges of at least two of the first bunch structures 20 are different. Such design of the shapes of the plurality of first bunch structures 20 allows the first bunch structures 20 to be adapted to some other shapes of the display region 11, such as the oval display region 11 in the embodiments shown in FIG. 6. Optionally, in the embodiments shown in FIG. 9, the shape formed by sequentially connecting the plurality of second ends 201b of a portion of the first bunch structures 20 is approximately a circle, and the shape formed by sequentially connecting the plurality of second ends 201b of a portion of the first bunch structures 20 is approximately a circle with one, two, or three depressions, or other shapes. This design allows the radial dimensions of the draining structure 2 to be more uniform throughout the curved edge of the display region 11.

Therefore, the shapes of the edges of the plurality of first bunch structures 20 is identical, or the shapes of the edges of at least two of the first bunch structures 20 are different, which can be adapted to the display region 11 with different shapes.

Optionally, as shown in FIG. 9, the plurality of first bunch structures 20 includes a first target rib structure 2011 and a second target rib structure 2012, and the distance between the first bunch structure group 20a to which the first target rib structure 2011 belongs and the display region 11 is shorter than the distance between the first bunch structure group 20a to which the second target rib structure 2012 belongs and the display region 11. The length of the first target rib structure 2011 is different from the length of the second target rib structure 2012. By designing the first target rib structure 2011 and the second target rib structure 2012 to have different lengths, the first bunch structure 20 with different edge shapes is thereby formed. e.g., in the embodiment shown in FIG. 9, the length of the first target rib structure 2011 is greater than the length of the second target rib structure 2012 and the first bunch structure 20 to which the first target rib structure 2011 belongs is shorter than the distance between the first bunch of structures 20 to which the second target rib structure 2012 the first bunch structure 20 to which the first target rib structure 2011 belongs is adjacent to the first bunch structure 20 to which the second target rib structure 2012 belongs.

In other possible embodiments, in the case that the display region 11 is oval as shown in FIG. 9, the plurality of first bunch structures 20 also constitute only one first bunch structure group 20a, and there are at least two first bunch structures 20 with different shapes.

FIG. 10 is a schematic diagram of a planar structure of another display panel and a schematic diagram of the arrangement of the corresponding first bunch structures according to some embodiments of the present disclosure. As shown in FIG. 10, in the case that the shape of the display region 11 is circular, the plurality of first bunch structures 20 also constitute only one first bunch structure group 20a. In other possible embodiments, for a circular display region 11, the plurality of first bunch structures 20 are divided into a plurality of first bunch structure groups 20a.

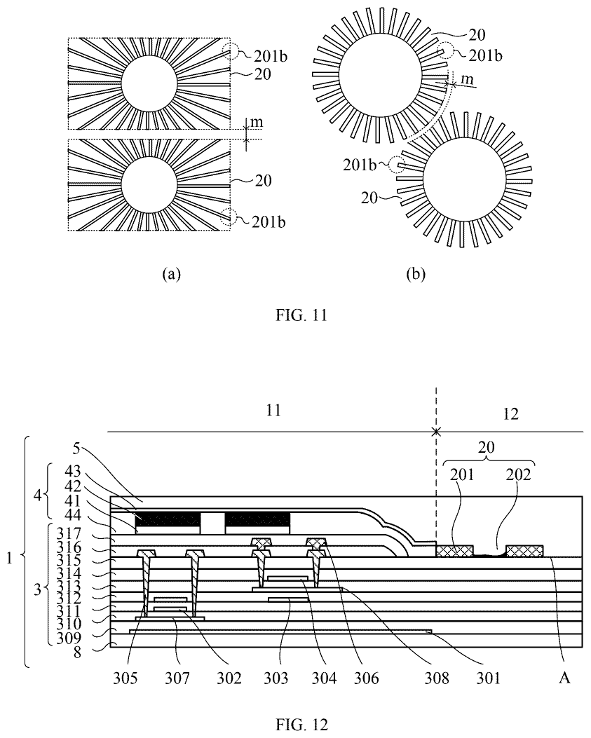

FIG. 11 is a schematic diagram of the planar structure of two adjacent first bunch structures according to some embodiments of the present disclosure. As shown in FIG. 11, part (a) of FIG. 11 illustrates two adjacent first bunch structures 20, and the shape formed by sequentially connecting the plurality of second ends 201b of the two first bunch structures 20 is a rectangle. Part (b) of FIG. 11 illustrates the two first bunch structures 20, and the shape formed by sequentially connecting the plurality of second ends 201b of the two first bunch structures 20 is approximately a circle. The spacing 0 m between the two adjacent first bunch structures 20 ranges from 2 μm to 8 μm, for example, 2 μm, 4 ˜m, 6 μm, or 8 μm. The distance between the two adjacent first bunch structures 20 herein refers specifically to the distance between the shapes of the two adjacent first bunch structures 20, for example, the shortest distance m between any point on the edge of the graphs of one of the first bunch structures 20 and the edge of the shape of the other first bunch structure 20. It is also required to maintain a certain distance between the edges of the shapes of the two adjacent first bunch structures 20 in order to form an air column carrying droplets on the first rib structure 201. A too short distance is not beneficial to forming the air column, and a too long distance causes the droplets on the first rib structure 201 to fall directly to the bottom of the first bunch structure 20, affecting the effect of flow directing.

FIG. 12 is a schematic diagram of a cross-sectional structure of another display panel according to some embodiments of the present disclosure. As shown in FIG. 12, the display substrate 1 includes a substrate 8, a driving circuit layer 3, and a light-emitting functional layer 4 which are sequentially stacked, and the driving circuit layer 3 and the light-emitting functional layer 4 are disposed in the display region 11. The driving circuit layer 3 includes a source-drain electrode layer, the first rib structures 201 are in the same layer as the source-drain layer, and the one-layer manufacturing can save the processes.

Optionally, the source-drain electrode layer is made of stacked metals such as titanium, aluminum, and titanium. Optionally, the titanium layer, the aluminum layer, and the titanium layer are sequentially stacked on the first surface A. The first rib structure and the source-drain electrode layer are disposed in the same layer. In the case that the titanium-aluminum-titanium stacked material is etching, since the etching speed of the aluminum is faster, the dimension of the groove in the transverse direction formed in the aluminum layer by etching is larger than the dimension of the groove in the transverse direction in the titanium layer, and an I-shape structure is formed to facilitate manufacturing the I-shape first rib structure 201.

Exemplarily, as shown in FIG. 12, the driving circuit layer 3 and the substrate 8 are referred to as a driving backplane, and the driving backplane shown in FIG. 11 is a low-temperature polycrystalline oxide (LTPO) backplane.

The following is an exemplary description of the structure of the layers of the LTPO backplane in the embodiments shown in FIG. 12.

Exemplarily, as shown in FIG. 11, the driving circuit layer 3 includes a light shielding layer 301, a buffer layer 309, a first semiconductor layer 307, a first gate insulating layer 310, a first gate layer 302, a first insulating layer 311, a second gate layer 303, a second gate insulating layer 312, a second semiconductor layer 308, a third gate insulating layer 313, a third gate layer 304, an interlayer dielectric layer 314, a passivation layer 315, a first source-drain layer 305, a first planarization layer 316, a second source-drain layer 306, and a second planarization layer 317. The first source-drain layer 305 or the second source-drain layer 306 is the above source-drain layer. In the embodiments shown in FIG. 11, the first rib structure 201 is in the same layer as the second source-drain layer 306.

Exemplarily, the substrate 8 is any transparent substrate, such as a glass substrate, a quartz substrate, a plastic substrate, other transparent rigid substrate, or other transparent flexible substrate, which has a single-layer or a multi-layer structure. Taking the multi-layer structure as an example, the substrate 8 includes a first polyimide (PI) layer, a first protective layer, a second PI layer, and a second protective layer which are stacked in an order from bottom to top, and the two protective layers are configured to protect the PI layer and prevent damage to the PI layer from subsequent processes. The second protective layer is also covered by a buffer layer that blocks water, oxygen, and alkaline ions.

Exemplarily, the fabrication material of the light-shielding layer 301 is a metallic material, including but not limited to molybdenum, aluminum, titanium, copper, and other materials. The light-shielding layer 301 reduces the exposure of the thin film transistor (TFT) to light and is also capable of conducting electricity. The light-shielding layer 301 is also referred to as a bottom shield metal (BSM) layer.

Exemplarily, the first semiconductor layer 307 is made of a low-temperature polysilicon material, and the second semiconductor layer 308 is made of a metal oxide semiconductor material such as indium gallium zinc oxide (IGZO).

Exemplarily, the materials of the first gate insulating layer 310, the first insulating layer 311, the second gate insulating layer 312, the third gate insulating layer 313, and the interlayer dielectric layer 314 are a silicon oxide, a silicon nitride, a silicon nitride oxide, or the like.

Exemplarily, the materials of the first gate layer 302, the second gate layer 303, and the third gate layer 304 are metallic materials, such as one or more of molybdenum, copper, aluminum, titanium.

Exemplarily, the material of the passivation layer 315 is a silicon oxide layer, a silicon nitride layer, or a silicon oxide layer.

Exemplarily, the first planarization layer 316 and the second planarization 317 layer are made of an organic insulating material, such as a resin.

In other possible embodiments, the driving backplane including the driving circuit layer 3 and the substrate 8 is a low temperature poly-silicon (LTPS) backplane. For the LTPS backplane, the driving circuit layer 3 includes a first gate layer, a first gate insulating layer, a first semiconductor layer, a second gate insulating layer, a second gate layer, an interlayer dielectric layer, a passivation layer, a first source-drain layer, and a first planarization layer which are sequentially stacked on the first surface A. The first gate insulating layer is a first source-drain layer. The first source-drain layer is the above source-drain layer. The material of each layer is the same as the above LTPO backplane portion, which are not repeated herein.

In the embodiments of the present disclosure, the display panel is an organic light emitting diode (OLED) display panel, or a quantum dot light emitting diode (QLED) display panel. The OLED display panel is shown in the embodiments shown in FIG. 11. The following is an exemplary description of the light-emitting functional layer 4 of the OLED display panel shown in FIG. 12.

Exemplarily, as shown in FIG. 12, the light-emitting functional layer 4 includes a first electrode layer 41, a light-emitting layer 42, and a second electrode layer 43 which are sequentially stacked on the first surface A. The light-emitting layer 42 is an organic light-emitting layer. The draining structure in the embodiments of the present disclosure can direct the organic light-emitting liquid material into the first collection groove 202.

Exemplarily, the first electrode layer 41 includes a plurality of first electrodes arranged in an array, and the plurality of first electrodes is in one-to-one correspondence with the plurality of sub-pixels.

Exemplarily, the first electrode layer 41 is an anode layer, made of a metal material, such as gold, silver, etc., or made of a transparent conductive material, such as indium tin oxide (ITO), or the like.

Exemplarily, the light-emitting layer 42 includes a plurality of light-emitting blocks arranged in an array, the plurality of light-emitting blocks is in one-to-one correspondence with the plurality of pixels, and the colors of the plurality of light-emitting blocks are different, so as to achieve a color display function. Optionally, the colors of the plurality of light-emitting blocks include red, green, and blue.

Exemplarily, the second electrode layer 43 has a whole layer structure. The first electrode, the light-emitting blocks, and a portion of the second electrode layer form a light-emitting unit, and one light-emitting unit corresponds to one sub-pixel.

Exemplarily, the second electrode layer 43 is a cathode layer and is made of a transparent conductive material, such as ITO and the like.

Exemplarily, as shown in FIG. 12, the light-emitting functional layer 4 further includes a pixel definition layer 44, and the pixel definition layer 44 is disposed between two adjacent first electrodes and between two adjacent light-emitting blocks. The pixel definition layer 44 is configured to separate different first electrodes and light-emitting blocks, and divide a plurality of light-emitting units.

Exemplarily, the light-emitting layer 42 is an organic light-emitting layer. The light-emitting layer 42 includes a hole injection layer (HIL), a hole transport layer (HTL), an electron blocking layer (EBL), a light-emitting material layer, a hole blocking layer (HBL), an electron transport layer (ETL), and an electron injection layer (EIL) which are stacked sequentially on the first surface A. The light-emitting material layer is made of an organic light-emitting material. The draining structure in the embodiments of the present disclosure can direct, for example, HTL liquid material, HIL liquid material, and the like into the first collection groove 202. Moreover, for a plurality of light-emitting blocks having different colors, the light-emitting material layers of the plurality of light-emitting blocks are different, but the HIL, HTL, and the like of the plurality of light-emitting blocks are the same, i.e., the HIL, HTL, and other film layers are in a common layer. The common layer is generally formed as a film by an all-round coating manner, and the embodiments of the present disclosure is particularly suitable for the separating film layers of the HIL, HTL, and the like formed by the all-round coating manner.

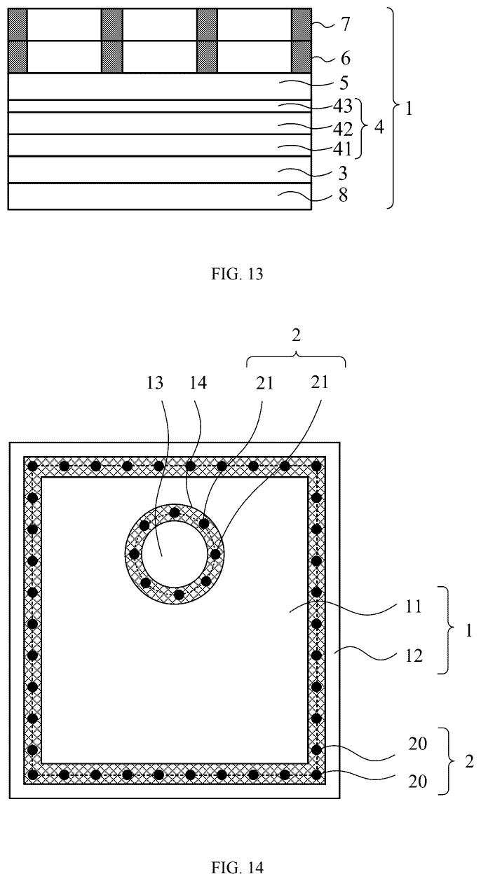

FIG. 13 is a schematic diagram of a cross-sectional structure of a display region of another display panel according to some embodiments of the present disclosure. Compared to the embodiments shown in FIG. 12, in the embodiments shown in FIG. 13, the display panel is a QLED display panel, and correspondingly, the light-emitting layer 42 is a quantum dot light-emitting layer. The draining structure in the embodiments of the present disclosure can direct the quantum dot light-emitting material liquid into the first collection groove 202.

Optionally, compared to the embodiments shown in FIG. 12, in the embodiments shown in FIG. 13, the light-emitting layer 42 is a quantum dot light-emitting layer. Optionally, in the embodiments shown in FIG. 13, HIL, HTL, EBL, the light-emitting material layer, HBL, ETL, and EIL are sequentially stacked on the first surface A, wherein the light-emitting material layer is made of quantum dot light-emitting material.

Furthermore, in the embodiments shown in FIG. 13, the display substrate 1 further includes a color transfer layer 6 and a color film layer 7.

Optionally, the color film layer 7 includes a plurality of color blocks arranged in an array, and a black matrix disposed between two adjacent color resist blocks. The color transfer layer 6 includes a plurality of color transfer units arranged in an array, the plurality of color transfer units is in one-to-one correspondence with the plurality of color blocks, and orthographic projections of the plurality of color transfer units on the first surface A are at least partially overlapped with orthographic projections of the plurality of color blocks on the first surface A.

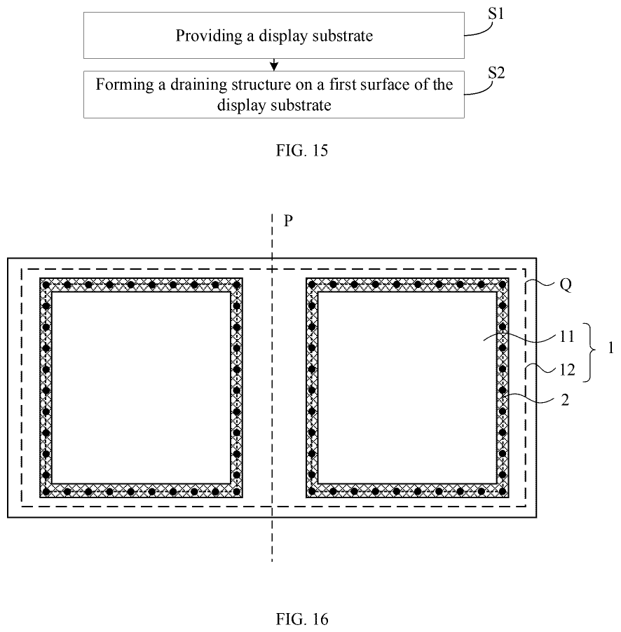

FIG. 14 is a schematic diagram of a planar structure of another display panel according to some embodiments of the present disclosure. As shown in FIG. 14, the display substrate 1 further includes an opening region 13 and a second peripheral region 14, the display region 11 surrounds the opening region 13, and the second peripheral region 14 is disposed between the opening region 13 and the display region 11. The draining structure 2 further includes a plurality of second bunch structures 21, and the plurality of second bunch structures 21 are disposed in the second peripheral region 14. The plurality of second bunch structures 21 is arranged around the opening region 13, each of the second bunch structures 21 has a second collection groove, and each of the second bunch structures 21 includes a plurality of second rib structures arranged in a circumferential row around the second collection groove, and the plurality of second rib structures is configured to direct droplets into the second collection groove surrounded by the plurality of second rib structures. The draining structure in the embodiments of the present disclosure are also applied to a display panel having an opening region. When manufacturing, for example, a light-emitting layer, the film layer formed by the droplets on the draining structure in the second peripheral region is isolated to avoid forming a connecting path upon drying, such that the external water and oxygen entering into the interior of the display panel through the connecting path is prevented from affecting the encapsulation effect of the display panel.

In other possible embodiments, the display substrate 1 further includes a plurality of opening regions 13 and a plurality of second peripheral regions 14, the display region 11 surrounds the plurality of opening regions 13, the plurality of second peripheral regions 14 are in one-to-one correspondence with the plurality of opening regions 13, and the plurality of second peripheral regions 14 is disposed between the plurality of opening regions 13 and the display region 11. The draining structure 2 further includes a plurality of second bunch structures 21, the plurality of second bunch structures 21 are disposed in the plurality of second peripheral regions 14, and the plurality of second bunch structures 21 is arranged around the plurality of opening regions 13.

Optionally, the shape of the opening regions 13 is circular as shown in FIG. 14, or be a waist-shaped circle, a rectangle, ore the like, which is not limited in the present disclosure.

Optionally, the design manner of the second collection groove and the second rib structure in the second bunch structure 21 is described in the above first collection groove and the above first rib structure in the first bunch structure 20.

Optionally, the plurality of second bunch structures 21 are arranged in a manner referable to the above arrangement of the plurality of first bunch structures 20 described.

FIG. 15 is a flow chart of a method for manufacturing a display panel according to some embodiments of the present disclosure. As shown in FIG. 15, the method includes the follows.

In step S1, a display substrate is provided, wherein the display substrate includes a display region and a first peripheral region disposed at an edge of the display region.

In step S2, a draining structure is formed on a first surface of the display substrate.

The draining structure includes a plurality of first bunch structures, the plurality of first bunch structures is disposed in the first peripheral region, the plurality of first bunch structures is arranged around the display region, each of the first bunch structure has a first collection groove, each of the first bunch structures includes a plurality of first rib structures arranged in a circumferential row around the first collection groove, and the plurality of first rib structures is configured to direct droplets into the first collection groove surrounded by the plurality of first rib structures.

The step S2 is exemplarily described below with the structure shown in FIGS. 1 and 13 as an example. Exemplarily, the step S2 includes the following steps.

In a first step, a light masking metal layer is deposited on the substrate, and then the light masking layer is patterned to acquire the light masking layer, which is disposed in the display region.

In a second step, a buffer layer is formed on the light masking layer by, for example, deposition. A first semiconductor material layer is formed on the buffer layer by, for example, deposition, and patterned to acquire the first active layer.

In a third step, an initial first gate insulating layer and a first gate material layer are formed sequentially on the first active layer by, for example, deposition. The initial first gate insulating layer covers the first active layer. The first gate material layer is patterned to obtain the first gate layer. Optionally, a conductivity process is performed for a portion of the first active layer not covered by the first gate layer to ensure a good ohmic contact between the first active layer and the first source-drain layer formed subsequently.

In a fourth step, an initial first insulating layer and a second gate material layer are sequentially formed on the first gate layer by, for example, deposition. The second gate material layer is patterned to acquire a second gate layer.

In a fifth step, an initial second gate insulating layer and a second semiconductor material layer are sequentially formed on the second gate layer by, for example, deposition, and the second semiconductor material layer is patterned to acquire a second active layer.

In a sixth step, an initial third gate insulating layer and a third gate material layer are formed sequentially on the second active layer by, for example, deposition. The initial third gate insulating layer covers the second active layer. The third gate material layer is patterned to acquire the third gate layer. Optionally, a conductivity process is performed for a portion of the second active layer not covered by the third gate layer to ensure a good ohmic contact between the second active layer and the second source-drain layer formed subsequently.

In a seventh step, an initial interlayer dielectric layer and an initial passivation layer are sequentially formed on the third gate layer by, for example, deposition. On the initial passivation layer, a plurality of vias exposing the light shielding layer, the first active layer, and the second active layer is formed by a series of processes such as photoresist coating, exposing, etching, and stripping. The first gate insulating layer is acquired from the initial first gate insulating layer, the first insulating layer is acquired from the initial first insulating layer, the second gate insulating layer is acquired from the initial second gate insulating layer, the third gate insulating layer is acquired from the initial third gate insulating layer, and the interlayer dielectric layer is acquired from the initial interlayer dielectric layer, and the passivation layer is acquired from the initial passivation layer.

In an eighth step, the first source-drain layer is formed in the vias acquired in step 7 by a series of processes such as deposition, photoresist coating, exposing, etching, stripping, and the like.

In a ninth step, an initial first planarization layer is thus formed on the first source-drain patterned layer by, for example, deposition, and the initial first planarization layer is patterned to remove the initial first planarization layer disposed in the first peripheral region. Through a series of processes such as photoresist coating, exposing, etching, and stripping, a plurality of vias exposing the first source-drain layer are formed, and the first planarization layer is acquired from the initial first planarization layer simultaneously.

In a tenth step, within the vias acquired by etching in the ninth step and in the first peripheral region, a second source-drain pattern layer is formed by a series of processes such as, for example, deposition, photoresist coating, exposing, etching, stripping, and the like, and the second source-drain pattern layer includes the second source-drain layer disposed in the display region and a plurality of first bunch structures disposed in the first peripheral region.

In an eleventh step, the initial second planarization layer is formed on the second source-drain pattern layer by, for example, deposition. The initial second planarization layer is patterned, and the initial second planarization layer disposed in the first peripheral region is removed to acquire the second planarization layer.

In a twelfth step, a first electrode layer is formed by means of, for example, deposition as well as patterning, the first electrode layer including a plurality of first electrodes. A pixel definition layer is formed on the first electrode layer by means of, for example, deposition as well as patterning treatment.

In a thirteenth step, the liquid HIL material is coated by full coating, wherein the droplets of the HIL material on the draining structure are directed by the first rib structure into the first collection groove to form the HIL. The HTL and the EBL are formed sequentially by the same manner as forming the HIL.

Optionally, prior to forming the HIL, HTL, and EBL, a lyophobic film is formed on a surface, away from the first surface, of the plurality of first bunch structures by, for example, deposition. Upon coating the liquid HIL, HTL or EBL material, the external stimulation such as light and temperature is performed on the draining structures, which enhances the lyophobic properties of the surfaces of the first rib structures, and facilitates the first rib structures in directing the droplets into the first collection groove.

Optionally, prior to drying the droplets, adsorption treatment to the droplets in the first collection groove can remove most of the droplets in the first collection groove, such that only a very small amount of solute is left upon drying the droplets, which is beneficial to enhancing the encapsulation effect of the display panel. For example, the droplets can be sucked up by a syringe, and the method is convenient for mass production.

Optionally, upon drying the droplets, the droplets in the first collection groove are wiped. For example, a cotton swab is used for wiping. Optionally, a solvent such as an alcohol solvent, acetone, or toluene is used for the wiping treatment, such that the solute left in the first collection groove upon drying the droplets is dissolved, and different solvents can be selected based on different film layers.

In a fourteenth step, a light-emitting layer is formed by, for example, inkjet printing, wherein the light-emitting layer includes a plurality of light-emitting blocks arranged in an array. Optionally, a plurality of red light-emitting blocks arranged in an array are formed first, then a plurality of green light-emitting blocks arranged in an array are formed, and finally a plurality of blue light-emitting blocks arranged in an array is formed.

In a fifteenth step, HBL, ETL, and EIL are formed by a manner similar to that in the thirteenth step.

In a sixteenth step, a second electrode layer disposed in the display region is formed by, for example, deposition and patterning treatment. An encapsulation layer is formed by, for example, deposition, or the like, and the encapsulation layer covers the display region and the first peripheral region.

Optionally, the patterning treatment includes processes such as photoresist coating, exposing, development, etching, stripping, and the like.

The materials of each layer are described in the above embodiments, which are not repeated herein.

FIG. 16 is a schematic diagram of a light-emitting layer formed by an all-round coating manner according to some embodiments of the present disclosure. Two display panels shown in FIG. 16, or more display panels, are produced simultaneously. Correspondingly, in the thirteenth and fifteenth steps, the liquid material is coated on the surfaces of the plurality of display panels, and the coating boundary is Q. Due to the draining structure 2, the light-emitting layers of the different display regions 11 are separated. Optionally, an adsorption treatment or a wiping treatment is performed on the droplets in the regions other than the display region 11 and the draining structure 2. Optionally, a plurality of display panels is divided along the division line P prior to the encapsulation process.

Embodiments of the present disclosure also provide a display device including any of the above display panels and a power supply circuit, wherein the power supply circuit is configured to supply power to the display panels.

Exemplarily, the display device provided by the embodiments of the present disclosure may be a cellular phone, a tablet computer, a television, a monitor, a laptop computer, a digital photo frame, a navigator, and any other product or component having a display function.

The display device has the same effect as the above display panel, which are not repeated herein.

The above are only optional embodiments of the present disclosure and are not intended to limit the present disclosure, and any modifications, equivalent replacements, improvements, or the like made within the spirit and principles of the present disclosure shall be included in the scope of protection of the present disclosure.

1. A display panel, comprising a display substrate and a draining structure, wherein the display substrate comprises a display region and a first peripheral region disposed at an edge of the display region, and the draining structure is disposed on a first surface of the display substrate;
wherein the draining structure comprises a plurality of first bunch structures, the plurality of first bunch structures is disposed in the first peripheral region, the plurality of first bunch structures is arranged around the display region, each of the first bunch structure has a first collection groove, each of the first bunch structure comprises a plurality of first rib structures arranged in a circumferential row around the first collection groove, and the plurality of first rib structures is configured to direct droplets into the first collection groove surrounded by the plurality of first rib structures.

2. The display panel according to claim 1, wherein each of the first rib structures has a first end close to the first collection groove and a second end away from the first collection groove, and a distance between two of the first rib structures adjacent in the circumferential row is gradually increasing in a direction from the first end to the second end.

3. The display panel according to claim 2, wherein in at least one of the first bunch structures, the first ends of the plurality of first rib structures are connected.

4. The display panel according to claim 2, wherein the plurality of first bunch structures is divided into at least two first bunch structure groups, the at least two first bunch structure groups are arranged in a direction away from the display region, and first bunch structures in each of the first bunch structure groups are arranged sequentially in a circumferential row around the display region.

5. The display panel according to claim 2, wherein the plurality of first bunch structures is sequentially arranged in a circumferential row around the display region.

6. The display panel according to claim 4, wherein a shape formed by sequentially connecting second ends of the plurality of first rib structures of each of the first bunch structures is identical.

7. The display panel according to claim 4, wherein
for two adjacent first bunch structure groups among the at least two first bunch structure groups, a length of at least a part of the plurality of first rib structures of a first bunch structure group which is further away from the display region is shortened to avoid a first bunch structure group which is closer to the display region.

8. The display panel according to claim 1, wherein a distance between two adjacent first bunch structures ranges from 2 μm to 8 μm.

9. The display panel according to claim 1, wherein a diameter of the first collection groove ranges from 1 mm to 10 mm, and a depth of the first collection groove ranges from 0.5 μm to 5 =m.

10. The display panel according to claim 1, wherein the first rib structure has a cross-sectional shape in a length direction of the first rib structure of one of an I-beam and a T-shape.

11. The display panel according to claim 1, wherein a length of the first rib structure ranges from 10 μm to 500 μm.

12. The display panel according to claim 1, wherein the display substrate comprises a substrate, a driving circuit layer and a light-emitting functional layer which are stacked sequentially, and the driving circuit layer and the light-emitting functional layer are disposed in the display region, wherein the driving circuit layer comprises a source-drain layer, and the first rib structures are in the same layer as the source-drain layer.

13. The display panel according to claim 12, wherein the light-emitting functional layer comprises a first electrode layer, a light-emitting layer and a second electrode layer which are stacked sequentially on the first surface;
wherein the light-emitting layer is one of an organic light-emitting layer and a quantum dot light-emitting layer.

14. The display panel according to claim 1, wherein the draining structure further comprises a lyophobic film, and the lyophobic film is disposed on a side, away from the first surface, of the plurality of first bunch structures.

15. The display panel according to claim 1, wherein the display substrate further comprises at least one opening region and at least one second peripheral region, the display region surrounds each of the at least one opening region, the at least one second peripheral region is in one-to-one correspondence with the at least one opening region, and each of the at least one second peripheral region is disposed between a corresponding opening region and the display region; and
the draining structure further comprises a plurality of second bunch structures, the plurality of second bunch structures are disposed in the at least one second peripheral region, the plurality of second bunch structures is arranged around each of the at least one opening region, each of the second bunch structures has a second collection groove, and each of the second bunch structures comprises a plurality of second rib structures arranged in a circumferential row around the second collection groove, and the plurality of second rib structures is configured to direct droplets into the second collection groove surrounded by the plurality of second rib structures.

16. A method for manufacturing a display panel, comprising:
providing a display substrate, wherein the display substrate comprises a display region and a first peripheral region disposed at an edge of the display region; and
forming a draining structure on a first surface of the display substrate;
wherein the draining structure comprises a plurality of first bunch structures, the plurality of first bunch structures is disposed in the first peripheral region, the plurality of first bunch structures is arranged around the display region, each of the first bunch structure has a first collection grooves, each of the first bunch structures comprises a plurality of first rib structures arranged in a circumferential row around the first collection groove, and the plurality of first rib structures is configured to direct droplets into the first collection groove surrounded by the plurality of first rib structures.

17. A display device, comprising a power supply circuit and a display panel, wherein the power supply circuit is configured to supply power to the display panel, and the display panel comprises a display substrate and a draining structure, wherein the display substrate comprises a display region and a first peripheral region disposed at an edge of the display region, and the draining structure is disposed on a first surface of the display substrate;
wherein the draining structure comprises a plurality of first bunch structures, the plurality of first bunch structures is disposed in the first peripheral region, the plurality of first bunch structures is arranged around the display region, each of the first bunch structure has a first collection groove, each of the first bunch structure comprises a plurality of first rib structures arranged in a circumferential row around the first collection groove, and the plurality of first rib structures is configured to direct droplets into the first collection groove surrounded by the plurality of first rib structures.

18. The display panel according to claim 4, wherein shapes formed by sequentially connecting second ends of the plurality of first rib structures of at least two of the first bunch structures are different.

19. The display device according to claim 17, wherein each of the first rib structures has a first end close to the first collection groove and a second end away from the first collection groove, and a distance between two of the first rib structures adjacent in the circumferential row is gradually increasing in a direction from the first end to the second end.

20. The display device according to claim 19, wherein in at least one of the first bunch structures, the first ends of the plurality of first rib structures are connected.
